(19) United States
(12) Patent Application Publication
(10) Pub. No.: US 2024/0257318 A1
(43) Pub. Date: Aug. 1, 2024

(54) SYSTEM AND METHOD OF CONVERTING DIFFRACTION PATTERN IMAGE FOR INTERCONVERTING SYNTHETIC TEM SADP IMAGE AND REAL TEM SADP IMAGE USING DEEP LEARNING

(71) Applicant: LightVision Inc., Seoul (KR)

(72) Inventors: Jin Ha JEONG, Yongin-si (KR); Moon Soo RA, Bucheon-si (KR); Hea Yun LEE, Suwon-si (KR); Hyun Ji LEE, Seoul (KR)

(21) Appl. No.: 18/629,462

(22) Filed: Apr. 8, 2024

Related U.S. Application Data
(63) Continuation of application No. PCT/KR2022/015361, filed on Oct. 12, 2022.

(30) Foreign Application Priority Data
Oct. 18, 2021 (KR) 10-2021-0138141
Dec. 3, 2021 (KR) 10-2021-0171533

(51) Int. Cl. G06T 5/60; G06T 11/00; H01J 37/22; H01J 37/26

(52) U.S. Cl. CPC G06T 5/60; G06T 11/00; H01J 37/222; G06T 2207/10056; G06T 2207/20081; H01J 37/26

(57) ABSTRACT

A system and a method of generating adaptively a TEM SADP image with high discernment according to inputted parameters are disclosed. The system for converting a diffraction pattern image includes a real diffraction pattern image refining unit configured to remove unnecessary information from a real diffraction pattern image; a synthetic diffraction pattern generating unit configured to obtain a synthetic diffraction pattern image corresponding to the real diffraction pattern image in which the unnecessary information is removed; and a real-synthetic interconversion algorithm learning unit configured to generate an image belonging to a real diffraction pattern domain from an image belonging to a synthetic diffraction pattern domain or generate an image belonging to the synthetic diffraction pattern domain from an image belonging to the real diffraction pattern domain by using at least one of the real diffraction pattern image in which the unnecessary information is removed and the synthetic diffraction pattern image.

### CROSS-REFERENCE TO RELATED APPLICATIONS

This application is a Bypass continuation of pending PCT International Application No. PCT/KR2022/015361, which was filed on Oct. 12, 2022, and which claims priorities under 35 U.S.C 119(a) to Korean Patent Application No. 10-2021-0138141 filed with the Korean Intellectual Property Office on Oct. 18, 2021 and Korean Patent Application No. 10-2021-0171533 filed with the Korean Intellectual Property Office on Dec. 3, 2021. The disclosures of the above patent applications are incorporated herein by reference in their entirety.

### TECHNICAL FIELD

The disclosure relates to a system and a method of generating adaptively a TEM SADP image with high discernment according to inputted parameters.

The disclosure relates to a system and a method of converting a diffraction pattern image for interconverting synthetic TEM SADP image and real TEM SADP image using a deep learning.

### BACKGROUND ART

A bright point is shown at a central part of real TEM SADP image because the most amount of an electron beam passes through the central part. Peripheral diffraction points are not well shown because brightness of the bright point is higher than that of the peripheral diffraction points. Accordingly, a beam stopper is used for blocking the brightest point located at the central part as shown in FIG. 15 when the TEM SADP image is photographed. However, conventional simulation program does not consider effect of the beam stopper.

Additionally, various errors, such as an error occurred due to misalign of a direction of the electron beam and a zone axis, an error occurred in an optical system and an error occurred in a process of obtaining a diffraction pattern through an image sensor, e.g. CCD/CMOS, exist in the real TEM SADP image. However, the conventional simulation program does not consider influence by the errors.

Furthermore, quality or error of the TEM SADP image may differ according to a manufacturer of a TEM, but the conventional simulation program does not consider effect due to the difference.

### SUMMARY

The disclosure is to provide a system and a method of generating adaptively a TEM SADP image with high discernment according to inputted parameters.

Additionally, the disclosure is to provide a system and a method of generating synthetic diffraction pattern image which is usable for a TEM.

Furthermore, the disclosure is to provide a technique for preventing a ringing effect or a phenomenon that high order Laue Zone (HOLZ) or blurred diffraction point is included in the diffraction pattern image.

Moreover, the disclosure is to provide a technique for generating a diffraction pattern image by interpreting mathematically parameters inputted by a user.

In addition, the disclosure is to provide a computing device with rapid processing speed using a parallel processing of a CPU or a GPGPU.

Furthermore, the disclosure is to provide a technique using an image processing technique such as gamma correction.

Moreover, the disclosure is to provide a technique using the SADP image generated adaptively depending on inputted parameters.

Additionally, the disclosure is to provide a technique for preventing a phenomenon that material is broken down because an electron beam is emitted to the material too many times.

Furthermore, the disclosure is to provide a system and a method of converting a diffraction pattern image for interconverting synthetic TEM SADP image and real TEM SADP image by using a deep learning.

A system for converting a diffraction pattern image according to an embodiment of the disclosure includes a real diffraction pattern image refining unit configured to remove unnecessary information from real diffraction pattern image; a synthetic diffraction pattern generating unit configured to obtain a synthetic diffraction pattern image corresponding to the real diffraction pattern image in which the unnecessary information is removed; and a real-synthetic interconversion algorithm learning unit configured to generate an image belonging to a real diffraction pattern domain from an image belonging to a synthetic diffraction pattern domain or generate an image belonging to the synthetic diffraction pattern domain from an image belonging to the real diffraction pattern domain by using at least one of the real diffraction pattern image in which the unnecessary information is removed and the synthetic diffraction pattern image.

A system for converting a diffraction pattern image according to another embodiment of the disclosure includes a real diffraction pattern image refining unit configured to remove unnecessary information from real diffraction pattern image; a synthetic diffraction pattern generating unit configured to obtain a synthetic diffraction pattern image corresponding to the real diffraction pattern image in which the unnecessary information is removed; and an algorithm learning unit configured to generate a diffraction pattern image belonging to real diffraction pattern domain from a diffraction pattern image belonging to a synthetic diffraction pattern domain by using a deep learning algorithm learned with at least one of the real diffraction pattern image and the synthetic diffraction pattern image.

A system for converting a diffraction pattern image according to still another embodiment includes a real diffraction pattern image refining unit configured to remove unnecessary information from real diffraction pattern image; a synthetic diffraction pattern generating unit configured to obtain a synthetic diffraction pattern image corresponding to the real diffraction pattern image in which the unnecessary information is removed; and an algorithm learning unit configured to generate a diffraction pattern image belonging to a synthetic diffraction pattern domain from a diffraction pattern image belonging to a real diffraction pattern domain by using a deep learning algorithm learned with at least one of the real diffraction pattern image and the synthetic diffraction pattern image.

A recording medium readable by a computer recording a program code according to an embodiment of the present embodiment, the program code being used for performing a method includes removing unnecessary information from real diffraction pattern image; generating a synthetic diffraction pattern image corresponding to the real diffraction pattern image in which the unnecessary information is removed; and generating an image belonging to real diffraction pattern domain from an image belonging to a synthetic diffraction pattern domain or generating the image belonging to the synthetic diffraction pattern domain from the image belonging to the real diffraction pattern domain by using at least one of the real diffraction pattern image in which the unnecessary image is removed and the synthetic diffraction pattern image.

A system and a method of generating a TEM SADP image according to an embodiment of the disclosure may prevent a phenomenon that high order Laue zone (HOLZ) or blurred diffraction point is included in a diffraction pattern and a ringing effect of the diffraction pattern occurred due to a discontinuity point of a light source according to inputted parameters.

A system for converting a diffraction pattern image according to an embodiment of the disclosure generates a TEM SADP image corresponding to synthetic TEM SADP image, and thus various errors likely to occur in real TEM experiment may be simulated. Here, the generated TEM SADP image is similar to real TEM SADP image.

### BRIEF DESCRIPTION OF DRAWINGS

Example embodiments of the disclosure will become more apparent by describing in detail example embodiments of the disclosure with reference to the accompanying drawings, in which:

FIG. 1 is a view illustrating an example of real TEM SADP image;

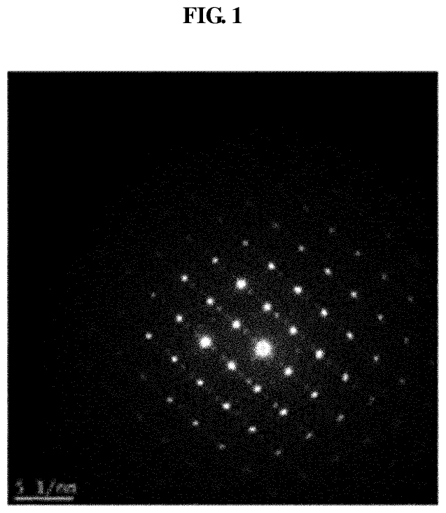

FIG. 2 is a view illustrating synthetic SADP image generated through a JEMS program;

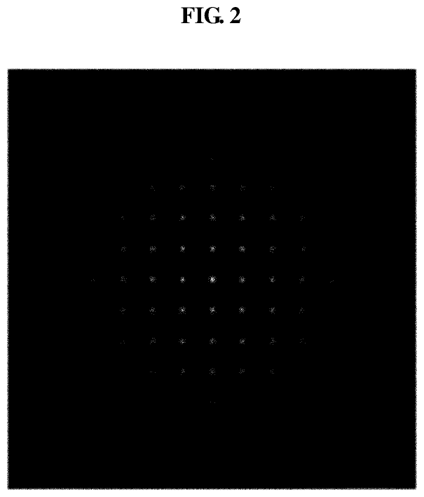

FIG. 3 is a view illustrating an SADP image where HOLZ pattern is included;

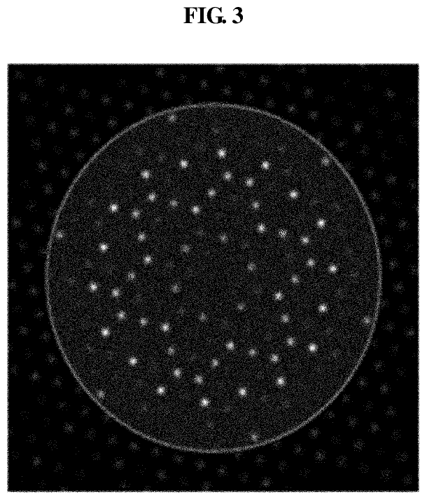

FIG. 4 is a view illustrating an SADP image where blurred diffraction point is included;

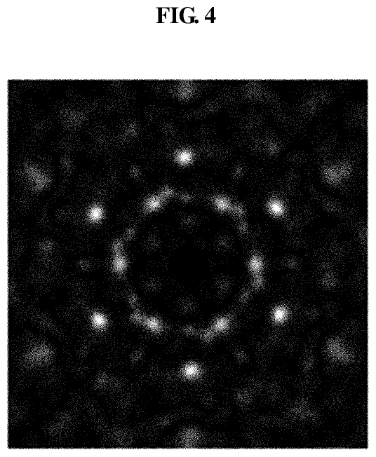

FIG. 5 is a view illustrating an SADP image to which a ringing effect occurs;

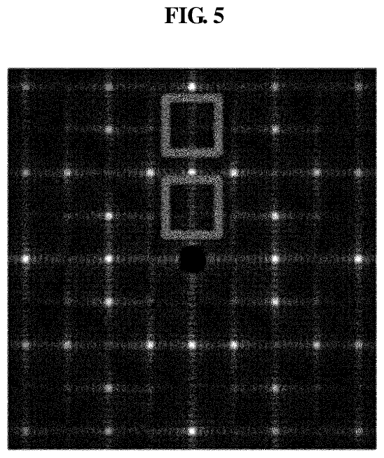

FIG. 6 is a block diagram illustrating schematically a system for generating a TEM SADP image according to an embodiment of the disclosure;

FIG. 7 is a view illustrating an SADP image to which a ringing effect does not occur generated by using a method of generating the TEM SADP image of the disclosure;

FIG. 8 is a view illustrating an example of lattice constant of material included in a cubic system;

FIG. 9 is a view illustrating an example of lattice constant of material included in a hexagonal system;

FIG. 10 is a view illustrating relation among an electron beam, Eward sphere, reciprocal lattice and diffraction pattern;

FIG. 11 is a view illustrating unit lattice before aligned and unit lattice after aligned;

FIG. 12 is a view illustrating a slab-type sample generated by using unit lattice aligned with a zone axis according to an embodiment of the disclosure;

FIG. 13 is a view illustrating an example of a diffraction pattern generated by the system for generating the TEM SADP image according to the disclosure;

FIG. 14 is a view illustrating a system for interconverting real TEM SADP image and synthetic TEM SADP image according to an embodiment of the disclosure;

FIG. 15 is a view illustrating a process of blocking a bright point located at a central part of an image by using a beam stopper;

FIG. 16 is a view illustrating an example of real TEM SADP image in which scale information is shown;

FIG. 17 is a view illustrating real TEM SADP image in which the scale information is erased;

FIG. 18 is a view illustrating an example of synthetic TEM SADP image generated through a JEMS program;

FIG. 19 is a view illustrating an example of a TEM SADP image similar to real TEM SADP image from synthetic TEM SADP image; and

FIG. 20 is a view illustrating a real-synthetic interconversion algorithm according to an embodiment of the disclosure.

### DETAILED DESCRIPTION

In the present specification, an expression used in the singular encompasses the expression of the plural, unless it has a clearly different meaning in the context. In the present specification, terms such as “comprising” or “including,” etc., should not be interpreted as meaning that all of the elements or operations are necessarily included. That is, some of the elements or operations may not be included, while other additional elements or operations may be further included. Also, terms such as “unit,” “module,” etc., as used in the present specification may refer to a part for processing at least one function or action and may be implemented as hardware, software, or a combination of hardware and software.

The disclosure relates to a system and a method of generating adaptively a TEM (Transmission Electron Microscope) SADP (Selected Area Diffraction Pattern) image with high discernment according to inputted parameters. The system may generate excellent TEM SADP image with discernment, a ringing effect of a diffraction pattern due to a discontinuity point of a light source and a phenomenon that high order Laue zone (HOLZ) or blurred diffraction point is included in the diffraction pattern not being occurred to the TEM SADP image.

An SADP image is obtained by emitting an electron beam to material through a TEM to detect feature of the material, but the material may be broken down if the electron beam is emitted to the material too many times. Accordingly, the system may generate an SADP image by using a program without emitting the electron beam to the material so that the material is not broken down. The generated SADP image may be used in various fields.

Hereinafter, various embodiments of the disclosure will be described in detail with reference to accompanying drawings.

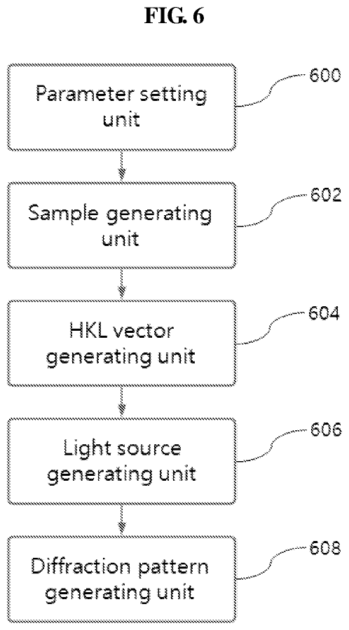

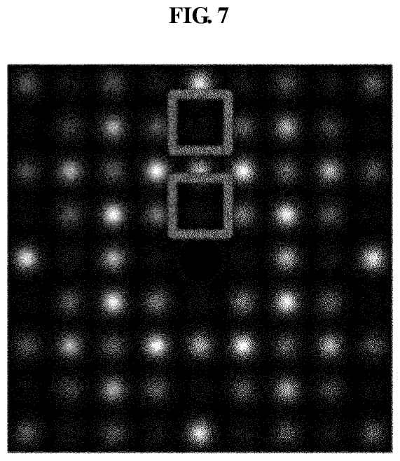

FIG. 6 is a block diagram illustrating schematically a system for generating a TEM SADP image according to an embodiment of the disclosure, and FIG. 7 is a view illustrating an SADP image to which a ringing effect does not occur generated by using a method of generating the TEM SADP image of the disclosure.

In FIG. 6, the system for generating a TEM SADP image of the present embodiment may generate adaptively an SADP image according to inputted parameters, the ringing effect of a diffraction pattern and a phenomenon that HOLZ or blurred diffraction point is included in the diffraction pattern not being occurred to the SADP image.

The system may include a parameter setting unit 600, a sample generating unit 602, an HKL vector generating unit 604, a light source generating unit 606, a diffraction pattern generating unit 608 and a controller (not shown) for controlling their operation. Here, the system may be embodied with one device, e.g., be a server, and it may be referred to as a computing device.

The parameter setting unit 600 may set parameters for generating the SADP image. For example, the parameter setting unit 600 may set the parameters through user's input.

In an embodiment, the parameter setting unit 600 may set parameters such as lattice constant, relative location of atom in unit lattice, a zone axis, wavelength and intensity of an electron beam, a distance to a camera, size of a diffraction pattern image and so on. Every parameter may be inputted by the user or the other parameter may be automatically generated if the user inputs a part of the parameters.

The sample generating unit 602 may generate a slab-type sample by using a parameter about the relative location of atom in unit lattice and a parameter about the zone axis. Here, the slab may have a shape of thin plate. Of course, the sample is not limited as the slab-type sample.

The HKL vector generating unit 604 may generate a reciprocal lattice vector meeting with synthetic Eward sphere. Here, the reciprocal lattice may be a parameter generated automatically by using specific program according to the unit lattice set by the parameter setting unit 600.

The light source generating unit 606 may calculate relative brightness of an electron beam reached to each of atoms in the sample.

The diffraction pattern generating unit 608 may generate synthetic SADP image by accumulating diffractions generated by interaction among every atom and every electron in the sample. In this time, the set parameters, the reciprocal lattice vector, relative brightness of the electron beam reached to the atom, etc. may be used.

Briefly, the system of generating the TEM SADP image of the present embodiment generates adaptively synthetic SADP image in response to various inputted parameters. Here, the ringing effect and the phenomenon that the HOLZ pattern or the blurred diffraction point is included in the diffraction pattern may not be occurred to the synthetic SADP image.

Additionally, the system may generate rapidly the SADP image by using parallel processing of a CPU or a GPGPU.

That is, the system may generate rapidly many synthetic SADP images. Here, the generated SADP images may be substantially identical to real SADP image.

In above description, specific parameters are mentioned as parameters inputted by the user. However, the parameter is not limited as long as the sample is generated by using the parameters inputted by the user.

That is, the system of generating the TEM SADP image may include a sample generating unit for generating the slab-type sample using the parameters inputted by the user, a light source generating unit for calculating the brightness of the electron beam reached to the atom in the sample by using inputted shape and intensity of the light source and the diffraction pattern generating unit for generating synthetic diffraction pattern image by using the calculated brightness of the electron beam.

On the other hand, the reciprocal lattice vector, the brightness of the electron beam and the diffraction pattern may be generated by applying mathematically the parameters inputted by the user. This will be described below.

In the above description, the user inputs the parameters to generate the TEM SADP image. However, the system may extract parameters from real SADP image and generate synthetic TEM SADP image using the extracted parameters. That is, the system may generate multiple synthetic TEM SADP images based on the real SADP image.

Furthermore, the number of layers of the slab, the reciprocal lattice vector and the brightness of the electron beam, etc. are not fixed, but they may be adaptively changed depending on the parameters inputted by the user or the parameters extracted from the real SADP image. This will be described below.

Hereinafter, a process of generating the TEM SADP image will be described in detail with reference to accompanying drawings.

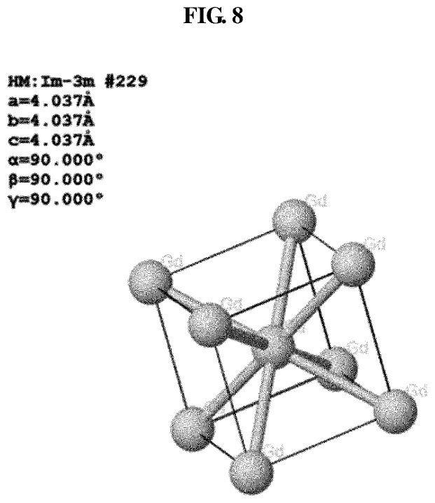

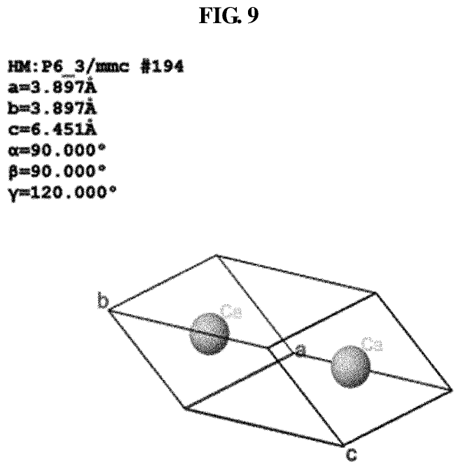

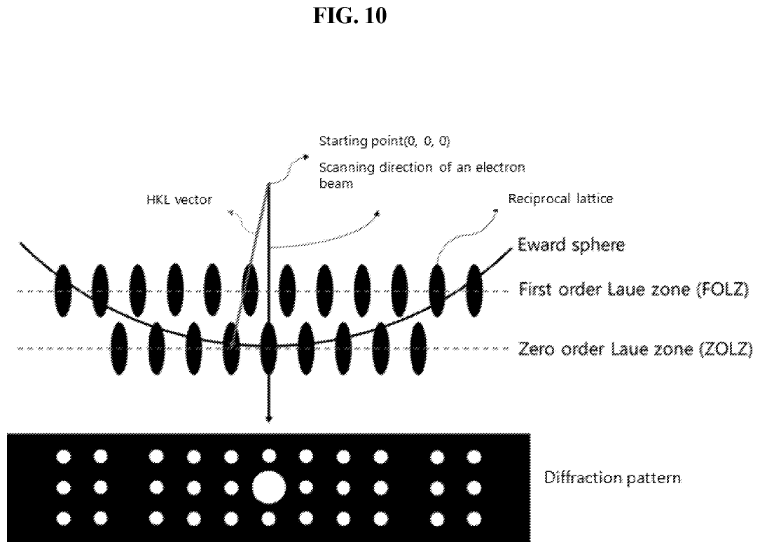

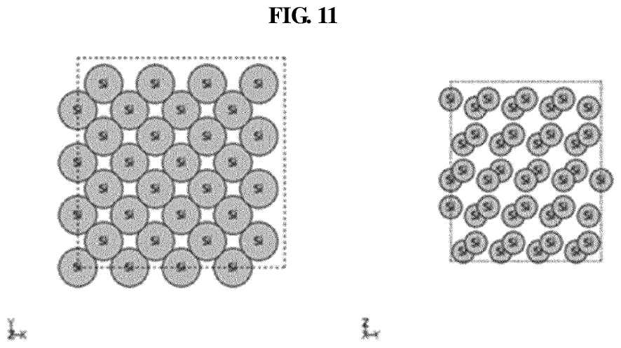

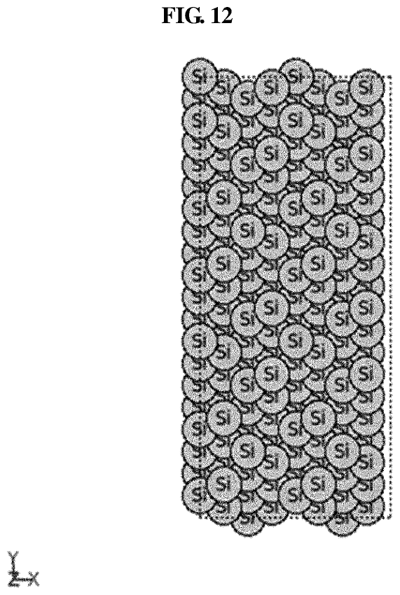

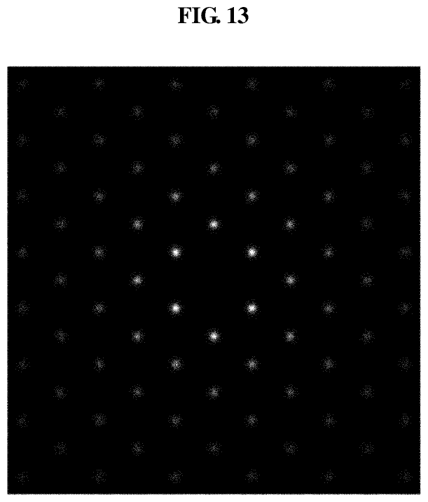

FIG. 8 is a view illustrating an example of lattice constant of material included in a cubic system. FIG. 9 is a view illustrating an example of lattice constant of material included in a hexagonal system, FIG. 10 is a view illustrating relation among an electron beam, Eward sphere, reciprocal lattice and diffraction pattern, and FIG. 11 is a view illustrating unit lattice before aligned and unit lattice after aligned. FIG. 12 is a view illustrating a slab-type sample generated by using unit lattice aligned with a zone axis according to an embodiment of the disclosure, and FIG. 13 is a view illustrating an example of a diffraction pattern generated by the system for generating the TEM SADP image according to the disclosure.

The parameter setting unit 600 may set parameters such as lattice constant, relative location of atom in unit lattice, a zone axis, wavelength and intensity of an electron beam, distance to a camera, size of a diffraction pattern image and so on. The parameters may be inputted by the user or be extracted from real SADP image.

Here, the lattice constant and the relative location of atom in the unit lattice may be inputted in CIF (Crystallography Information File) type, FHI-aims type or XYZ type.

The sample generating unit 602 may generate the slab-type sample by using inputted parameter about the lattice constant, inputted parameter about the relative location of atom in the unit lattice and inputted parameter about the zone axis.

Particularly, the lattice constant may comprise six parameters which include a, b, c, a, βand γ, wherein a, b and c correspond to size of a lattice vector and α, βand γcorrespond to angles between the lattice vectors. Material belongs to a cubic system if a-b-c, α=β=γ=90° as shown in FIG. 8, and the material belongs to a hexagonal system if a=b≠c, α=β=90°, γ=120° as shown in FIG. 9.

The relative location of atom in the unit lattice may be expressed in following table 1 when a three-dimensional space in the unit lattice is expressed in the range of 0 to 1.

TABLE 1
(relative location of atom in the unit lattice
of LiAl material belonging to the cubic system)

| Atomic | Relative location | | |
|---|---|---|---|
| symbol | x axis | y axis | z axis |
| Li | 0.0000 | 0.0000 | 0.5000 |
| Al | 0.0000 | 0.0000 | 0.0000 |

The sample generating unit 602 may generate the slab-type sample shown in FIG. 12 by aligning the unit lattice so that a lattice surface corresponding to the zone axis is vertical to a direction of the electron beam as shown in FIG. 11. Here, the slab-type sample may have a structure that unit lattices are disposed in platelike shape. The material in cubic system is generated in FIG. 12, but a sample in hexagonal system may be generated through the same process. Rodrigues formula may be used for aligning the direction of the electron beam in three-dimensional vector with the zone axis.

In an embodiment, the phenomenon that HOLZ or blurred diffraction point is included in the diffraction pattern may be prevented by determining adaptively the number of layers of the slab according to the inputted parameter about the lattice constant and the parameter about the zone axis.

That is, the sample generating unit 602 may determine adaptively the number of layers of the slab according to the inputted parameter about the lattice constant and the inputted parameter about the zone axis, to prevent the phenomenon that the HOLZ or blurred diffraction point is included in the diffraction pattern. Unit lattices may be aligned in the layers of the slab. As a result, the number of the layers of the slab may differ according to the parameters inputted by the user though the same material is used.

The HKL vector generating unit 604 may generate a reciprocal lattice vector meeting with synthetic Eward sphere as shown in FIG. 10. Diffraction may occur at a reciprocal lattice meeting with the Eward sphere, and thus the reciprocal lattice at which the diffraction occurs may be detected to calculate the diffraction pattern. Here, the reciprocal lattice may be parameters generated automatically by using specific program or equations according to the unit lattice set by the parameter setting unit 600.

Particularly, the HKL vector generating unit 604 may calculate a reciprocal lattice vector h(x,y), k(x,y), l(x,y) by using an image coordinate (x, y) separated from a starting point at which the electron beam locates by predetermined distance (d) and a wavelength (λ) of the electron beam as shown in following equation 1 and equation 2.

$$χ = \sqrt{{( \frac{x}{λ d} )}^{2} + {( \frac{y}{λ d} )}^{2} + {( \frac{1}{λ} )}^{2}} \qquad [ Equation 1 ]$$

$$h ( x , y ) = \frac{x}{{λ}^{2} d χ} , \qquad [ Equation 2 ]$$

$$k ( x , y ) = \frac{y}{{λ}^{2} d χ} ,$$

$$l ( x , y ) = \frac{1}{λ} - \frac{1}{{λ}^{2} χ}$$

As shown in equation 1, the HKL vector generating unit 604 may calculate ₓif the image coordinate (x, y), the wavelength (λ) and the distance (d) from the starting point at which the electron beam locates are known. The reciprocal lattice vector [h(x,y), k(x,y), l(x,y)] may be automatically calculated by using the calculated x.

The light source generating unit 606 may calculate the brightness of the electron beam reached to each of atoms in the sample by using inputted shape and intensity of a light source. Here, the shape of the light source may be flat based on a lattice surface vertical to the direction of the electron beam or have 2D Gaussian shape.

The brightness of the electron beam reached to each of atoms is shown in following equation 3 if the shape of the light source is flat when 3D location of the atom in the sample is (xj, yj, Zj).

$$I ( {x}_{j} , {y}_{j} , {z}_{j} ) = {I}_{0} . \qquad [ Equation 3 ]$$

Here, Io means intensity of the light source.

The brightness of the electron beam reached to each of atoms is shown in following equation 4 if the light source has 2D Gaussian shape.

$$I ( {x}_{j} , {y}_{j} , {z}_{j} ) = {I}_{0} exp ( - ( \frac{{( x - {x}_{j} )}^{2}}{{σ}_{x}^{2}} + \frac{{( y - {y}_{j} )}^{2}}{{σ}_{y}^{2}} ) ) \qquad [ Equation 4 ]$$

Here, Ox means a standard deviation at x axis, and oy means a standard deviation at y axis.

The brightness of the electron beam reached to each of atoms is shown in following equation 5 if the light source has 3D Gaussian shape.

$$I ( {x}_{j} , {y}_{j} , {z}_{j} ) = {I}_{0} exp ( - ( \frac{{( x - {x}_{j} )}^{2}}{{σ}_{x}^{2}} + \frac{{( y - {y}_{j} )}^{2}}{{σ}_{y}^{2}} + \frac{{( z - {z}_{j} )}^{2}}{{σ}_{z}^{2}} ) ) \qquad [ Equation 5 ]$$

Here, Oz means a standard deviation at z axis.

The light source generating unit 606 may use 3D Gaussian to generate continuous shape of the light source. In this case, a discontinuity point may not be occurred to an edge of the sample by setting 3σin Gaussian to have values smaller than a width, a length and a height of the sample.

In another embodiment, the light source generating unit 606 may remove a discontinuity point occurred in a width direction and a longitudinal direction of the sample by using 2D Gaussian or remove a discontinuity point occurred in a height direction of the sample by using an exponential decay function when the 2D Gaussian and the exponential decay function are simultaneously used.

On the other hand, the light source generating unit 606 may simulate the brightness lowered according as the electron beam passes through the sample by applying the exponential decay based on a direction of the electron beam. The light source to which the exponential decay is applied may be defined in following equation 6.

$${I}^{′} ( {x}_{j} , {y}_{j} , {z}_{j} ) = I ( {x}_{j} , {y}_{j} , {z}_{j} ) exp ( - {λ}_{d} {z}_{j} ) . \qquad [ Equation 6 ]$$

Here, λ_{d} means a parameter of the exponential decay.

Size and shape of the light source generated by the light source generating unit 606 may be adaptively changed depending on inputted size of the slap and inputted size of the diffraction pattern image, etc., and thus the ringing effect of the diffraction pattern occurred from the discontinuity point of the light source may be prevented. This is shown in FIG. 7. That is, the light source generating unit 606 may change adaptively the size and the shape of the light source according to the inputted size of the slab and the inputted size of the diffraction pattern image, to prevent the ringing effect of the diffraction pattern.

The diffraction pattern generating unit 608 may calculate accumulated diffraction pattern (F(h,k,l)) by using the reciprocal lattice vector [h(x,y), k(x,y), l(x,y)] calculated by the HKL vector generating unit 604, location of atom in the sample and the brightness of the electron beam (I(xj,yj,zj)) obtained by the light source generating unit 606 as shown in following equation 7.

$$F ( h , k , l ) = {\sum }_{j = 1}^{n} {f}_{oj} ( h , k , l ) I ( {x}_{j} , {y}_{j} , {z}_{j} ) cos \{ 2 π ( {hx}_{j} + {ky}_{j} + {lz}_{j} ) \} + i {\sum }_{j = 1}^{n} {f}_{oj} ( h , k , l ) I ( {x}_{j} , {y}_{j} , {z}_{j} ) sin \{ 2 π ( {hx}_{j} + {ky}_{j} + {lz}_{j} ) \} \qquad [ Equation 7 ]$$

Here, fₒⱼ(h,k,l) means jth scattering factor of atom. The scattering factor may differ according to kind of the atom.

Subsequently, the diffraction pattern generating unit 608 may calculate maximum value of the accumulated diffraction pattern and generate the diffraction pattern image by normalizing linearly the accumulated diffraction pattern based on the calculated maximum value.

In another embodiment, the diffraction pattern generating unit 608 may generate the diffraction pattern image by normalizing nonlinearly the accumulated diffraction pattern using an image process technique such as a gamma correction. Here, diffraction generated from interaction of atom and electron included in the sample may be independently calculated by the diffraction pattern generating unit 608, and thus an SADP image may rapidly calculated by using parallel processing of a CPU or a GPGPU (General Purpose computing on Graphics Processing Unit). The SADP image is shown in FIG. 13. As shown in FIG. 13, the ringing effect and the phenomenon that the HOLZ or the diffraction pattern is included in the diffraction pattern don't occur to the SADP image.

On the other hand, the diffraction pattern generating unit 608 may apply accumulated diffraction values to various functions to generate the SADP image. For example, the diffraction pattern generating unit 608 may generate the diffraction pattern image by applying a linear function or generate the diffraction pattern image by using a function used for gamma correction such as Vo=AVᵢ^{γ}.

Briefly, the system for generating the SADP image of the present embodiment may generate the SADP image by using the reciprocal lattice vector, the location of atom in the sample and the brightness of the electron beam, wherein the ringing effect and the phenomenon that the HOLZ or the blurred diffraction point is included in the diffraction pattern are not occurred to the SADP image.

Hereinafter, a system and a method of interconverting real TEM SADP image and synthetic TEM SADP image by using a deep learning will be described in detail with reference to accompanying drawings.

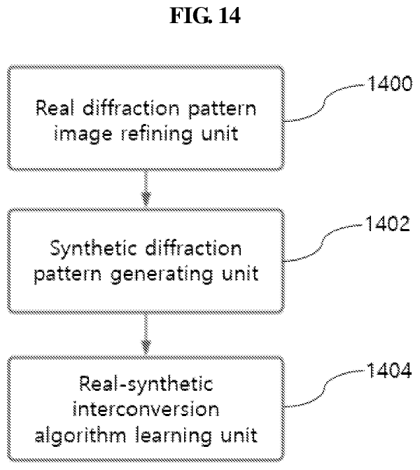

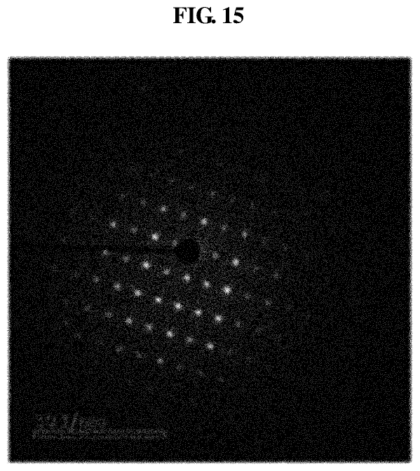

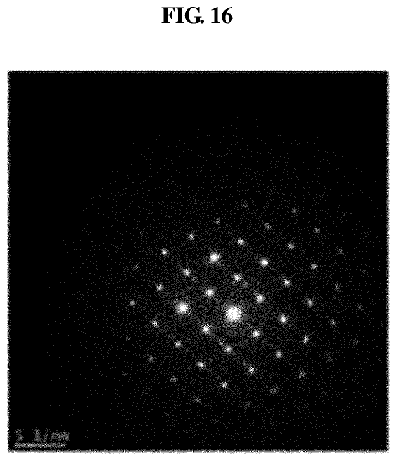

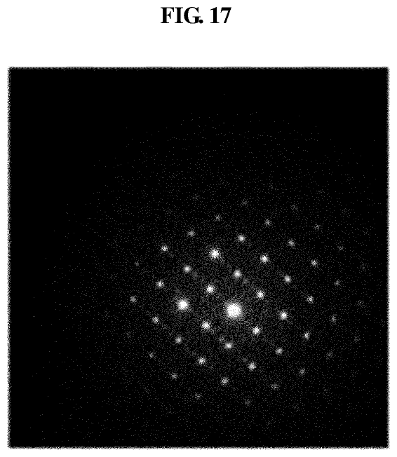

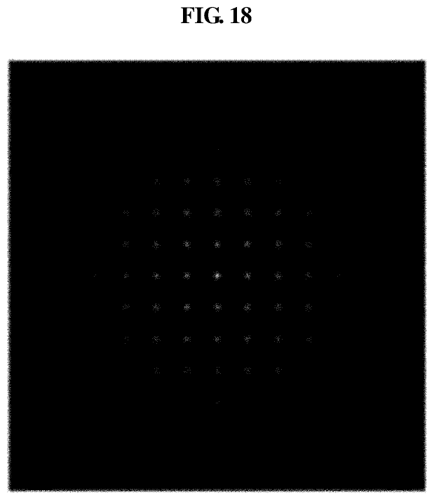

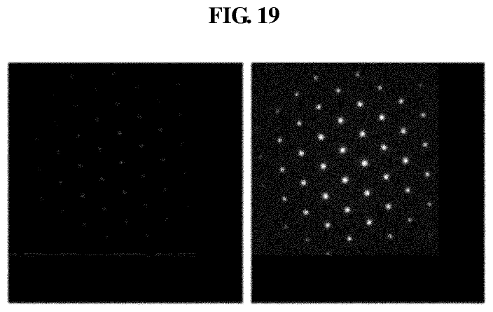

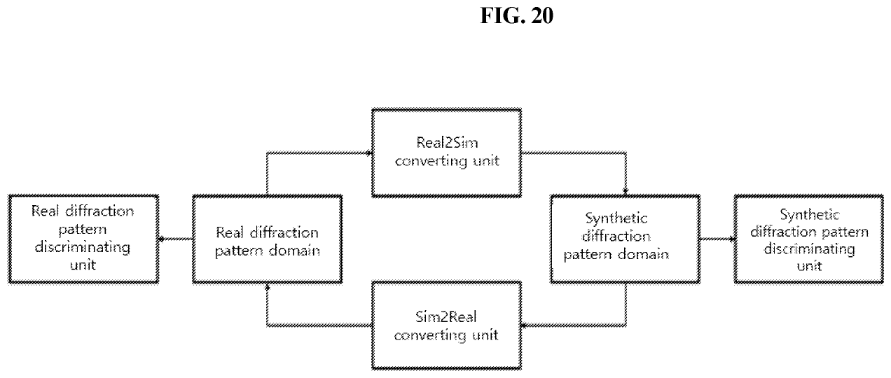

FIG. 14 is a view illustrating a system for interconverting real TEM SADP image and synthetic TEM SADP image according to an embodiment of the disclosure, FIG. 15 is a view illustrating a process of blocking a bright point located at a central part of an image by using a beam stopper, and FIG. 16 is a view illustrating an example of real TEM SADP image in which scale information is shown. FIG. 17 is a view illustrating real TEM SADP image in which the scale information is erased, FIG. 18 is a view illustrating an example of synthetic TEM SADP image generated through a JEMS program, and FIG. 19 is a view illustrating an example of a TEM SADP image similar to real TEM SADP image from synthetic TEM SADP image. FIG. 20 is a view illustrating a real-synthetic interconversion algorithm according to an embodiment of the disclosure.

A system for interconverting real TEM SADP image and synthetic TEM SADP image of the present embodiment includes a real diffraction pattern image refining unit 1400, a synthetic diffraction pattern generating unit 1402, a real-synthetic interconversion algorithm learning unit 1404 and a controller for controlling their operation.

The real diffraction pattern image refining unit 1400 may remove unnecessary part from real TEM SADP image, e.g. real TEM SADP image collected through an experiment or real TEM SADP image collected through a webpage.

For example, the real diffraction pattern image refining unit 1400 may remove annotation information, scale information, lattice surface index information, etc. added for recording additional information in the real TEM SADP image as shown in FIG. 15.

In an embodiment, the real diffraction pattern image refining unit 1400 may erase the annotation information from the real TEM SADP image and compose background on an erased area by using a commercial image processing program such as a Photoshop or a hole-filling algorithm for filling a damaged part of an image. An SADP image obtained through this process is shown in FIG. 17. Of course, a program is not limited as long as the program fills the erased area.

In another embodiment, the real diffraction pattern image refining unit 1400 may erase the scale information from real TEM SADP image in which the scale information is marked as shown in FIG. 16 and generate an SADP image by composing background on an erased area through the hole-filling algorithm, etc. as shown in FIG. 17.

The synthetic diffraction pattern generating unit 1402 may generate synthetic TEM SADP image corresponding to the real TEM SADP image by using a TEM SADP simulation program such as JEMS, QSTEM, abTEM, Ladyne Software Suite, SingleCrystal, Condor, etc. based on inputted parameter about the lattice constant and inputted parameter about the unit lattice. Here, the parameter about the lattice constant and the parameter about the unit lattice may be inputted by the user or be extracted from the real TEM SADP image.

Synthetic TEM SADP image generated by using a JEMS program is shown in FIG. 18 when information concerning the lattice constant and the unit lattice is provided in a CIF (Crystallography Information File) type, a FHI-aims type, a XYZ type. In this time, a method of generating an SADP image using one program may reduce confusion resulted from diversity of data in a learning process compared to a method of generating an SADP image using various programs because the generated synthetic SADP image is used for following learning of real-synthetic interconversion algorithm.

For example, the synthetic diffraction pattern generating unit 1402 may generate synthetic TEM SADP images corresponding to real TEM SADP image in which unnecessary part is removed by using the same JEMS program and may not use another program for generating the synthetic TEM SADP image.

In another embodiment, the synthetic diffraction pattern generating unit 1402 may select synthetic SADP image corresponding to the real TEM SADP image of synthetic TEM SADP images generated in FIG. 6 to FIG. 13.

In another aspect, the synthetic diffraction pattern generating unit 1402 may generate synthetic TEM SADP image corresponding to the real TEM SADP image through methods mentioned in FIG. 6 to FIG. 13.

Here, the synthetic diffraction pattern generating unit 1402 may include a sample generating unit for generating a sample by using at least one of a parameter about the lattice constant, a parameter about the relative location of atom in the unit lattice and a parameter about the zone axis, a vector generating unit for generating a reciprocal lattice vector corresponding to the unit lattice, a light source generating unit for calculating brightness of an electron beam reached to atom in the generated sample, a diffraction pattern generating unit for generating synthetic diffraction pattern image (TEM SADP image) using the generated reciprocal lattice vector, location of atom in the sample and the calculated brightness of the electron beam and a selection unit for selecting synthetic diffraction pattern image corresponding to the real diffraction pattern image of the generated synthetic diffraction pattern image.

The real-synthetic interconversion algorithm learning unit 1404 may learn a real-synthetic interconversion algorithm for generating an image belonging to a real diffraction pattern domain from an image belonging to a synthetic diffraction pattern domain or generating the image belonging to the synthetic diffraction pattern domain from an image belonging to the real diffraction pattern domain by using the real SADP image and the synthetic SADP image.

Subsequently, the real-synthetic interconversion algorithm learning unit 1404 may generate an SADP image belonging to the real diffraction pattern domain from an SADP image belonging to the synthetic diffraction pattern domain by using a deep learning model, i.e. a deep learning technique. For example, the real-synthetic interconversion algorithm learning unit 1404 may generate the SADP image shown in a right side in FIG. 19 from the synthetic SADP image shown in a left side in FIG. 19, the generated SADP image being similar to the real SADP image.

In this time, an algorithm requiring a pair of images belonging to two domains may be used if a synthetic diffraction pattern image having the same location of a diffraction point as real diffraction pattern is prepared. Whereas, an algorithm not requiring a pair of images belonging to two domains may be used if only one of the real diffraction pattern image and the synthetic diffraction pattern image is prepared.

The real-synthetic interconversion algorithm may generate the TEM SADP image similar to the real TEM SADP image considering effect of various errors included in the real TEM SADP image and effect of a beam stopper, through above process.

In another embodiment, the real-synthetic interconversion algorithm learning unit 1404 may generate the SADP image belonging to the real diffraction pattern domain from the SADP image belonging to the synthetic diffraction pattern domain and generate the SADP image belonging to the synthetic diffraction pattern domain from the SADP image belonging to the real diffraction pattern domain. An input will be real TEM SADP image if a deep learning application is created based on the TEM SADP image.

Here, a deep learning model learned with the SADP image belonging to the synthetic diffraction pattern domain may be used if inputted SADP image belonging to the real diffraction pattern domain is converted into the SADP image belonging to the synthetic diffraction pattern domain.

In FIG. 20, the real-synthetic interconversion algorithm learning unit 1404 may include a real diffraction pattern discriminating unit, a synthetic diffraction pattern discriminating unit, a Real2Sim converting unit and a Sim2Real converting unit.

The real diffraction pattern discriminating unit learns a deep learning model for discriminating a synthetic diffraction pattern converted through the Sim2Real converting unit from a diffraction pattern photographed through real TEM, the synthetic diffraction pattern being similar to the real diffraction pattern. Here, the synthetic diffraction pattern and the diffraction pattern photographed through the real TEM belong to the real diffraction pattern domain.

The synthetic diffraction pattern discriminating unit learns a deep learning model for discriminating real diffraction pattern converted through the Real2Sim converting unit from a synthetic diffraction pattern generated through a simulation, the real diffraction pattern being similar to the synthetic diffraction pattern. Here, the real diffraction pattern and the synthetic diffraction pattern generated through the simulation belong to the synthetic diffraction pattern domain.

The Real2Sim converting unit learns a deep learning model for converting the image belonging to the real diffraction pattern domain to the image belonging to the synthetic diffraction pattern domain. Here, an object of the Real2Sim converting unit is to generate very similar image so that the synthetic diffraction pattern discriminating unit can't discriminate an image generated thereby from the image generated through the simulation.

The Sim2Real converting unit learns a deep learning model for converting the image belonging to the synthetic diffraction pattern domain to the image belonging to the real diffraction pattern domain. Here, an object of the Sim2Real converting unit is to generate very similar image so that the real diffraction pattern discriminating unit can't discriminate an image generated thereby from the image photographed through real TEM.

Four elements in the real-synthetic interconversion algorithm learning unit 1404 affects to one another and learns a deep learning model performable well its object. Finally, the four elements may interconvert smoothly the image belonging to the real diffraction pattern domain and the image belonging to the synthetic diffraction pattern domain.

Since much time is required for obtaining real TEM SADP image through an experiment, a plenty of learning data set may be easily obtained if the deep learning mode learned with the SADP image belonging to the synthetic diffraction pattern domain is applied to real application. As a result, the application with high performance may be constructed.

Briefly, the system for interconverting the real TEM SADP image and the synthetic TEM SADP image may remove unnecessary information from collected real TEM SADP image, generate the synthetic TEM SADP image corresponding to the real TEM SADP image in which the unnecessary information is removed, and learn the real-synthetic interconversion algorithm by using the generated synthetic TEM SADP image and the real TEM SADP image. Here, the real-synthetic interconversion algorithm may generate the SADP image belonging to the real diffraction pattern domain from the SADP image belonging to the synthetic diffraction pattern domain, or generate the SADP image belonging to the synthetic diffraction pattern domain from the SADP image belonging to the real diffraction pattern domain.

Various errors occurred in real TEM experiment may be simulated by generating the TEM SADP image from the synthetic TEM SADP image, the TEM SADP image being similar to the real TEM SADP image.

Synthetic data generated through the simulation may be efficiently used for learning the deep learning model by reducing difference between the real TEM SADP image and the synthetic TEM SADP image through the real-synthetic interconversion algorithm when a deep learning application is created by using the TEM SADP image.

Components in the embodiments described above can be easily understood from the perspective of processes. That is, each component can also be understood as an individual process. Likewise, processes in the embodiments described above can be easily understood from the perspective of components.

Also, the technical features described above can be implemented in the form of program instructions that may be performed using various computer means and can be recorded in a computer-readable medium. Such a computer-readable medium can include program instructions, data files, data structures, etc., alone or in combination. The program instructions recorded on the medium can be designed and configured specifically for the present invention or can be a type of medium known to and used by the skilled person in the field of computer software. Examples of a computer-readable medium may include magnetic media such as hard disks, floppy disks, magnetic tapes, etc., optical media such as CD-ROM's, DVD's, etc., magneto-optical media such as floptical disks, etc., and hardware devices such as ROM, RAM, flash memory, etc. Examples of the program of instructions may include not only machine language codes produced by a compiler but also high-level language codes that can be executed by a computer through the use of an interpreter, etc. The hardware mentioned above can be made to operate as one or more software modules that perform the actions of the embodiments of the invention, and vice versa.

The embodiments of the invention described above are disclosed only for illustrative purposes. A person having ordinary skill in the art would be able to make various modifications, alterations, and additions without departing from the spirit and scope of the invention, but it is to be appreciated that such modifications, alterations, and additions are encompassed by the scope of claims set forth below.

What is claimed is:

1. A system for converting a diffraction pattern image comprising:
a real diffraction pattern image refining unit configured to remove unnecessary information from a real diffraction pattern image;
a synthetic diffraction pattern generating unit configured to obtain a synthetic diffraction pattern image corresponding to the real diffraction pattern image in which the unnecessary information is removed; and
a real-synthetic interconversion algorithm learning unit configured to generate an image belonging to a real diffraction pattern domain from an image belonging to a synthetic diffraction pattern domain or generate an image belonging to the synthetic diffraction pattern domain from an image belonging to the real diffraction pattern domain by using at least one of the real diffraction pattern image in which the unnecessary information is removed and the synthetic diffraction pattern image.

2. The system of claim 1, wherein the diffraction pattern image is a TEM (transmission electron microscope) SADP (selected area diffraction pattern) image.

3. The system of claim 2, wherein the unnecessary information is information concerning annotation, scale or index.

4. The system of claim 3, wherein the real diffraction pattern image refining unit detects the unnecessary information from the real diffraction pattern image and fills an area in which the unnecessary information locates using peripheral information of the detected unnecessary information through a hole-filling algorithm.

5. The system of claim 2, wherein the synthetic diffraction pattern generating unit uses a TEM SADP simulation program,
and wherein the TEM SADP simulation program generates a synthetic TEM SADP image corresponding to a real TEM SADP image based on inputted lattice constant and inputted unit lattice.

6. The system of claim 5, wherein information concerning the lattice constant and the unit lattice is provided in CIF (crystallography information file) type, FHI-aims type or XYZ type.

7. The system of claim 2, wherein the synthetic diffraction pattern generating unit includes:
a sample generating unit configured to generate a sample by using at least one of a parameter about lattice constant, a parameter about relative location of atom in unit lattice and a parameter about a zone axis;
a vector generating unit configured to generate a reciprocal lattice vector corresponding to the unit lattice;
a light source generating unit configured to calculate brightness of an electron beam reached to atom in the generated sample;
a diffraction pattern generating unit configured to generate the synthetic diffraction pattern image by using the generated reciprocal lattice vector, location of atom in the sample and the calculated brightness of the electron beam; and
a selection unit configured to select the synthetic diffraction pattern image corresponding to the real diffraction pattern image of the generated synthetic diffraction pattern image.

8. The system of claim 7, wherein the sample generating unit determines adaptively the number of layers of a slab according to the parameter about the lattice constant and the parameter about the zone axis of the inputted parameters so that a phenomenon that high order Laue Zone (HOLZ) or blurred diffraction point is included in a diffraction pattern are prevented, and
the light source generating unit changes adaptively a shape and intensity of the light source according to inputted size of the slab or inputted size of the diffraction pattern image so that a ringing effect of the diffraction pattern occurred from a discontinuity point of the light source is prevented.

9. The system of claim 2, wherein the real-synthetic interconversion algorithm learning unit generates a diffraction pattern image belonging to the real diffraction pattern domain from a diffraction pattern image belonging to the synthetic diffraction pattern domain by using a deep learning model.

10. The system of claim 9, wherein the real-synthetic interconversion algorithm learning unit generates the diffraction pattern image belonging to the real diffraction pattern domain from the diffraction pattern image belonging to the synthetic diffraction pattern domain by using specific algorithm when the real diffraction pattern image and the synthetic diffraction pattern image are prepared.

11. The system of claim 2, wherein the real-synthetic interconversion algorithm learning unit includes:
a Real2Sim converting unit;
a Sim2Real converting unit;
a real diffraction pattern discriminating unit configured to learn a deep learning model for discriminating a synthetic diffraction pattern image converted through the Sim2Real converting unit from a diffraction pattern image photographed through real TEM, the synthetic diffraction pattern image being similar to the real diffraction pattern image; and
a synthetic diffraction pattern discriminating unit configured to learn a deep learning model for discriminating the real diffraction pattern image converted through the Real2Sim converting unit from a synthetic diffraction pattern image generated through a simulation, the real diffraction pattern image being similar to the synthetic diffraction pattern,
and wherein the Real2Sim converting unit learns a deep learning model for converting an image belonging to the real diffraction pattern domain to an image belonging to the synthetic diffraction pattern domain, and
the Sim2Real converting unit learns a deep learning model for converting the image belonging to the synthetic diffraction pattern domain to the image belonging to the real diffraction pattern domain.

12. A system for converting a diffraction pattern image comprising:
a real diffraction pattern image refining unit configured to remove unnecessary information from a real diffraction pattern image;
a synthetic diffraction pattern generating unit configured to obtain a synthetic diffraction pattern image corresponding to the real diffraction pattern image in which the unnecessary information is removed; and
an algorithm learning unit configured to generate a diffraction pattern image belonging to a real diffraction pattern domain from a diffraction pattern image belonging to a synthetic diffraction pattern domain by using a deep learning algorithm learned with at least one of the real diffraction pattern image and the synthetic diffraction pattern image.

13. The system of claim 12, wherein the algorithm learning unit generates the diffraction pattern image belonging to the real diffraction pattern domain from the diffraction pattern image belonging to the synthetic diffraction pattern domain by using specific algorithm when the real diffraction pattern image and the synthetic diffraction pattern image are prepared.

14. A system for converting a diffraction pattern image comprising:
a real diffraction pattern image refining unit configured to remove unnecessary information from a real diffraction pattern image;
a synthetic diffraction pattern generating unit configured to obtain a synthetic diffraction pattern image corresponding to the real diffraction pattern image in which the unnecessary information is removed; and
an algorithm learning unit configured to generate a diffraction pattern image belonging to a synthetic diffraction pattern domain from a diffraction pattern image belonging to a real diffraction pattern domain by using a deep learning algorithm learned with at least one of the real diffraction pattern image and the synthetic diffraction pattern image.

15. A non-transitory computer readable medium storing a program code, wherein the program code, when executed by a processor, is used for performing a method comprising:
removing unnecessary information from a real diffraction pattern image;
generating a synthetic diffraction pattern image corresponding to the real diffraction pattern image in which the unnecessary information is removed; and
generating an image belonging to a real diffraction pattern domain from an image belonging to a synthetic diffraction pattern domain or generating the image belonging to the synthetic diffraction pattern domain from the image belonging to the real diffraction pattern domain by using at least one of the real diffraction pattern image in which the unnecessary image is removed and the synthetic diffraction pattern image.
